(19) United States
(12) Patent Application Publication
(10) Pub. No.: US 2006/0180935 A1
(43) Pub. Date: Aug. 17, 2006

(54) Semiconductor device

(75) Inventor: Norio Takatsu, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/345,500

(22) Filed: Feb. 2, 2006

(30) Foreign Application Priority Data
Feb. 14, 2005 (JP) 2005-036697

(51) Int. Cl. H01L 23/48

(52) U.S. Cl. 257/762

(57) ABSTRACT

A structure of a semiconductor device provided with a surface electrode can be simplified. Cu, which is a solderable metal, is employed for the gate electrode 101 and the source electrode 104 in a semiconductor device 100. Therefore, unlike as in the conventional technology, it is not necessary to separately form an additional solderable metal layer on the upper portions of the gate electrode and the source electrode.

This application is based on Japanese patent application No. 2005-36,697, the content of which is incorporated hereinto by reference.

### BACKGROUND

1. Technical Field

The present invention relates to a semiconductor device including a surface electrode.

2. Related Art

When surface electrode of a semiconductor device is connected to an external terminal with solder in the conventional technology, a barrier metal composed of two or three layers is required to be formed on an aluminum electrode via a photolithographic technology, in order to acquire an adhesiveness with solder and to acquire a reliability, and therefore a problem related to a production cost is incurred.

Thus, a metal having better adhesiveness with an aluminum electrode, such as zinc, titanium, chromium, palladium and the like is formed by an electroless plating process, and then nickel (Ni) or copper (Cu) is formed thereon as a barrier for solder, and furthermore, a metal for preventing an oxidation of Ni and Cu such as Au and the like is formed via the electroless plating process, and then a solder bump is formed by a screen printing process, thereby completing a manufacture of a semiconductor device having the solder bump (Japanese Patent Laid-Open No. H06-140,409 (1994)).

Since aluminum interconnects employed for interconnects of conventional semiconductor devices have a problem in solderability, as in the semiconductor device described in Japanese Patent Laid-Open No. H06-140,409, an additional metal layer is provided on the aluminum interconnect, in order to assure a solderability and to provide less deterioration in reliability caused by a counter diffusion with the aluminum electrode of the semiconductor device or with solder.

In another aspect, a solder bump is generally formed on the aforementioned aluminum electrode via the metal layer (barrier layer) in the conventional technology. On the contrary, transition to an use of a copper interconnect is proceeded in the modern semiconductor device, and correspondingly, a structure suitable for the copper interconnect is proposed, such as that a cohesion layer (aluminum (Al), titanium (Ti), chromium (Cr), cobalt (Co), nickel (Ni), molybdenum (Mo), silver (Ag), tantalum (Ta), tungsten (W,) gold (Au) or the like) is formed on a copper interconnect, and further a base metallic bump limited metal (BLM) film for bump is formed thereon, as in semiconductor devices described in Japanese Patent Laid-Open No. H11-340,265 (1999) and Japanese Patent Laid-Open No. 2002-110,799.

### SUMMARY OF THE INVENTION

However, the conventional technologies include the following problems. Description will be made in reference to FIG. 3 as follows.

A semiconductor device 10 includes a silicon substrate 9 having a device region in an upper portion thereof, a gate electrode 1 provided on the silicon substrate 9 via an insulating film 13 therebetween, gate interconnects 5, each of which is provided on the silicon substrate 9 so as to be embedded within an insulating film 8, a source electrode 4 provided on the gate interconnect 5 via a barrier metal 12 therebetween, and a drain electrode 6 provided on a lower surface of the silicon substrate 9. The source electrode 4 is composed of an aluminum interconnect. In addition, the semiconductor device 10 also includes metal layers 7 respectively disposed on the gate electrode 1 and on the source electrode 4, an anti-surface oxidization metal 3 provided on the metal layer 7, and a surface protective film 2. The metal layer 7 is composed of a solderable metal such as copper (Cu), nickel (Ni) and the like, and is formed via a plating process or the like.

In the semiconductor device 10, the source electrode 4 is composed of an aluminum interconnect, which is less than suitable for soldering. Thus, in order to assure the solderability thereof in such conventional configuration, it is necessary to separately form on the upper portion of the source electrode 4 an additional metal layer 7 for providing a contact with solder, which is composed of a metal that is solderable and provides an ensured junction reliability with aluminum and solder.

According to one aspect of the present invention, there is provided a semiconductor device, comprising: a semiconductor substrate including a device region; interconnects having a predetermined pattern and being provided on a surface of the semiconductor substrate; an insulating film provided to cover the interconnect; a first electrode provided on the semiconductor substrate to fill a space between the interconnects; and a second electrode electrically connected to the interconnect, the first electrode being electrically connected to the device region, and the first electrode being composed of a solderable metal.

According to the present invention, combined functions as a contact for forming a soldered joint and as an electrode can be achieved by providing the first electrode composed of a solderable metal, without a need for separately providing a solderable metal on the first electrode. Therefore, the structure of the semiconductor device provided with the first electrode that allows a manufacture thereof by a simple process can be obtained, while assuring the junction reliability between solder, which is provided when the semiconductor device is mounted to the substrate, and the first electrode.

According to the present invention, the structure of the semiconductor device, which allows the manufacture of the solderable and highly junction-reliable first electrode with a simple manufacturing process, can be obtained.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, schematically illustrating a semiconductor device according to an embodiment;

FIG. 2 is a cross-sectional view, schematically illustrating an exemplary implementation of mounting the semiconductor device on a printed circuit board according to the embodiment; and

FIG. 3 is a cross-sectional view, schematically illustrating a semiconductor device of a conventional technology.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, an identical numeral is assigned to an element commonly appeared in the figures, and the detailed description thereof will not be presented.

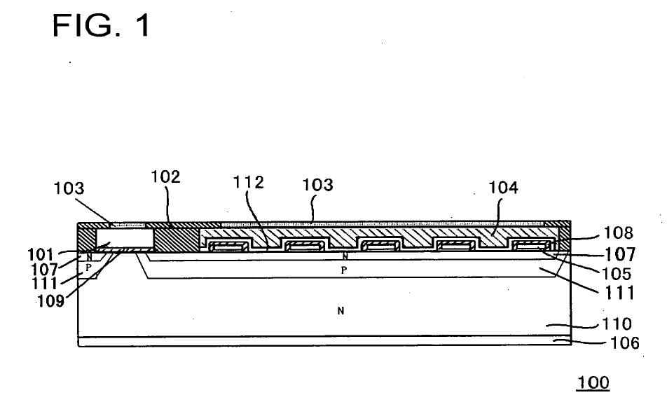

A semiconductor device 100 shown in FIG. 1 includes a semiconductor substrate (silicon substrate 110) that includes a device region (source region 107), interconnects (gate interconnects 105) that form a predetermined pattern provided on a surface of the semiconductor substrate, an insulating film (insulating film 108) that is provided so as to cover the interconnect, a first electrode (source electrode 104) that is a surface electrode provided on the semiconductor substrate so as to fill spaces between the interconnects, and a second electrode (gate electrode 101) that is electrically connected to the interconnect, and the first electrode is electrically connected to the device region. The first electrode is composed of a solderable metal, such as a metal including Cu, for example.

The semiconductor device 100 according to the present embodiment will be described in reference to FIG. 1.

The semiconductor device 100 is a metal oxide semiconductor field effect transistor (MOSFET), which includes a silicon substrate 110 that has a device region on an upper surface thereof, is doped with an n-type impurity and has a function as a drain region, a drain electrode 106 provided so as to contact with a back surface of the silicon substrate 110, a gate electrode 101 provided on a portion of the upper surface of the silicon substrate 110 via a gate insulating film 109 therebetween, and the source electrode 104 provided on the silicon substrate 110. Here, in the present embodiment, the semiconductor device 100 is a discrete device.

The source electrode 104 is connected to the source region 107 that is doped with an n-type impurity, and the drain electrode 106 is connected to the silicon substrate 110 that functions as a drain region. A channel diffusion region 111 doped with a p-type impurity is formed on the upper surface of the silicon substrate 110.

The semiconductor device 100 also includes, between the silicon substrate 110 and the source electrode 104, insulating films 108, gate interconnects 105, each embedded within the insulating film 108, and a barrier metal 112 provided on the insulating films 108. The semiconductor device 100 further includes a metal layer 103 formed on the gate electrode 101 and on the source electrode 104, and surface protective films 102 provided on the silicon substrate 110.

The gate electrode 101 and the source electrode 104 are composed of a solderable metal. Here, the “solderable metal” means, for example, a metal having better connectivity with solder such as lead free solder and better corrosion resistance to solder, and excludes aluminum. In the present embodiment, copper (Cu) is employed for the solderable metal. Thickness of the gate electrode 101 and the source electrode 104 may be preferably equal to or greater than 1.5 μm, and more preferably equal to or greater than 2.5 μm. Here, in the present embodiment, the thickness of the gate electrode 101 and the source electrode 104 are about 5 μm.

The gate electrode 101 and the source electrode 104 are simultaneously formed after the gate interconnect 105 is formed, by employing a sputter process or a filling processes.

Since the gate electrode 101 and the source electrode 104 are composed of Cu that has higher level of electroconductivity, electric resistances in the gate electrode 101 and the source electrode 104 can be reduced. Further, since Cu is employed, generation of a stress migration or the like can be inhibited, thereby providing an improved reliability of the semiconductor device 100.

Since the gate electrode 101 is provided on the silicon substrate 110 through gate insulating film 109, the gate electrode 101 is not electrically connected to the device region provided in the upper surface of the silicon substrate 110. The gate electrode 101 is electrically connected to the gate interconnects 105 through appropriate contacts (not shown).

The gate interconnects 105 are top layer interconnects provided on the surface of the semiconductor device 100, and forms a predetermined pattern. In the present embodiment, the gate interconnect 105 is composed of polysilicon, and the thickness of the gate interconnect 105 is smaller than the thickness of the gate electrode 101.

The source electrode 104 includes portions provided through the barrier metal 112 on the insulating films 108 that are respectively provided to surround the gate interconnects 105 and portions provided through the barrier metal 112 on the silicon substrate 110, as shown in FIG. 1. Since the source electrode 104 includes portions provided through the barrier metal 112 on the silicon substrate 110, the source electrode 104 is electrically connected to the source region 107 that is a device region provided above the silicon substrate 110. The source electrode 104 is provided so as to fill spaces created between a plurality of gate interconnects 105.

The insulating film 108 is composed of, for example, SiO₂, SiOC or the like, and functions to provide insulations between the gate interconnect 105 and the barrier metal 112 provided in the periphery of the insulating film 108.

The gate insulating film 109 is composed of, for example, SiO₂, SiOC or the like, and functions to provide an insulation between the gate electrode 101 and the silicon substrate 110.

In the semiconductor device 100, a diffusion barrier film (barrier metal 112) is provided between the upper surface of the insulating film 108 and the source electrode 104 and between portions of the upper surface of silicon substrate 110 and the source electrode 104.

The source electrode 104 is provided so that the barrier metal 112 is embedded therein.

The barrier metal 112 is provided between the upper surface of the insulating film 108 and the source electrode 104 and between portions of the upper surface of the silicon substrate 110 and the source electrode 104. The barrier metal 112 is composed of Ti/TiN and the like, and functions as inhibiting ion diffusion of Cu that composes the source electrode 104.

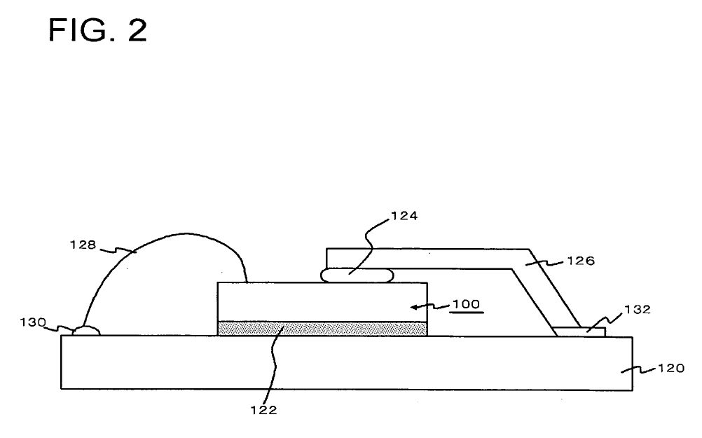

The drain electrode 106 is electrically connected to an interconnect pattern (not shown) provided in a printed circuit board 120 (FIG. 2) via a mounting material 122 (FIG. 2) so as to contact with the lower surface thereof.

The surface protective film 102 is composed of a polyimide film or the like, and functions as protecting the device region provided in the silicon substrate 110.

In the semiconductor device 100, a layer (metal layer 103) for inhibiting oxidation of the surface of the source electrode 101 is formed so as to contact with the upper surface of the source electrode 101. The metal layer 103 functions as inhibiting oxidation of the surfaces of the gate electrode 101 and the source electrode 104, and in the present embodiment, the metal layer 103 is formed by providing Au via an electroless plating process.

A configuration of mounting the semiconductor device 100 to a circuit board 120 will be described in reference to FIG. 2.

The printed circuit board 120 includes an interconnect pattern 132 and a pad 130 that is wire-bonded to the gate electrode 101 via a wire 128.

The interconnect pattern 132 is electrically connected to the source electrode 104 via a copper plate 126 and via a solder layer 124, which is provided so as to contact with the upper surface of the source electrode 104.

The drain electrode 106 is electrically connected to an interconnect pattern (not shown) provided in the upper surface of the printed circuit board 120 via the mounting material 122 that is electroconductive.

Advantageous effects obtainable by employing the configuration of the semiconductor device 100 will be described as follows.

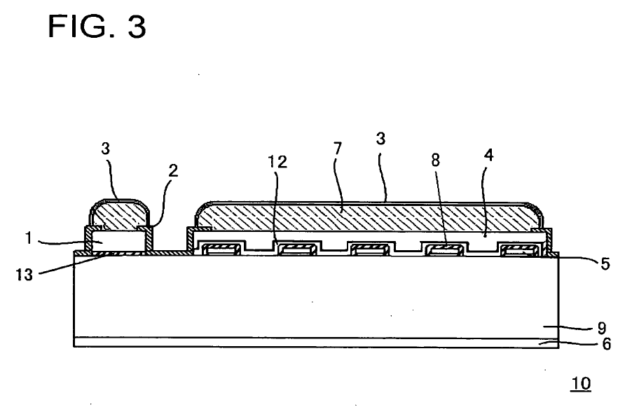

In the semiconductor device 100, copper (Cu), which is a metal being capable of forming a junction with solder, is employed for the gate electrode 101 and the source electrode 104. Therefore, it is not necessary to separately form an additional solderable metal layer on the upper portions of the gate electrode 1 and the source electrode 4 for providing contacts, unlike as the conventional technology described in reference to FIG. 3. The source electrode 104, which is a surface electrode, exhibits combined functions as the source electrode of the MOSFET and as the contact for the soldered junction. Accordingly, the structure of the semiconductor device 100 that can be manufactured by a simple process, as compared with the conventional technology described in reference to FIG. 3, can be obtained. Further, since the structure of the semiconductor device 100 can be simplified, as compared with the structure in the conventional technology described in reference to FIG. 3, the soldered junction can be easily formed. In addition, the upper surfaces of the gate electrode 101 and the source electrode 104 can be planarized. Therefore, larger solderable area can be obtained, as compared with the technology described in reference to FIG. 3. Therefore, a wider process allowance for providing a junction to the gate electrode 101 or the source electrode 104 with solder can be achieved.

In this case, Cu is employed for the gate electrode 101 and the source electrode 104. Therefore, electric resistances across the gate electrode 101 and across the source electrode 104 can be reduced, as compared with a case of employing aluminum, which has been frequently employed for the gate electrode 1 and the source electrode 4 in the conventional technology. Therefore, the electric resistance of the whole semiconductor device 100 can be reduced. In addition, power consumption of the semiconductor device 100 can be reduced.

Since a conventional technology utilizing a BLM film, which has been conventionally employed for reducing a manufacturing fluctuation of a solder bump and for maintaining a reliability thereof, is used in the technologies described in Japanese Patent Laid-Open No. H11-340,265 and Japanese Patent Laid-Open No. 2002-110,799, a problem of an increased process time is incurred. On the contrary, the semiconductor device 100 according to the present embodiment can prevent an alloy of the electrode material and solder created in forming a solder joint between the source electrode 104 and the solder layer 124, from reaching the device region provided on the silicon substrate 110, by selecting sufficient thickness of the gate electrode 101 and the source electrode 104, which are both equal to or greater than 1.5 μm. Therefore, the reliability of the semiconductor device 100 can be further improved. Further, the semiconductor device 100 according to the present embodiment can moreover prevent the alloy of the electrode material and solder from reaching the device region provided on the silicon substrate 110, by selecting more sufficient thickness of the gate electrode and the source electrode 104, which are both equal to or greater than 2.5 μm. Therefore, reliability of the semiconductor device 100 can further be improved.

Further, since it is not necessary to provide a barrier layer for preventing an alloy of the electrode material and solder from reaching the device region provided on the silicon substrate 110, necessary process operations for manufacturing the semiconductor device 100 can be reduced, thereby reducing the cost for manufacturing the semiconductor device 100.

In addition, since it is not necessary to separately form an additional solderable metal layer on the upper portions of the gate electrode 101 and the source electrode 104, necessary process operations for manufacturing the semiconductor device 100 can be reduced while maintaining the reliability of the semiconductor device 100, thereby reducing the cost for manufacturing the semiconductor device 100.

While the preferred embodiments of the present invention have been described above in reference to the annexed figures, it should be understood that the disclosures above are presented for the purpose of illustrating the present invention, and various configurations other than the above described configurations can also be adopted.

For example, the configuration employing a discrete device for the semiconductor device 100 has been described in the above-described embodiment, other device such as a power device with a control circuit and the like may also be employed.

In addition, while the configuration having the thickness of the gate electrode 101 and the source electrode 104 of about 5 μm has been described in the above-described embodiment, other thickness may also be selected, provided that the selected thickness provides an advantageous effect that is equivalent to the advantageous effect of the above-described embodiments.

Further, while the configuration comprising the gate electrode 101 and the source electrode 104 that are composed of Cu has been described in the above-described embodiment, other type of solderable metal such as Cu alloy, Ni and the like may also be employed.

Further, while the configuration comprising the metal layer 103 composed of Au has been described in the above-described embodiment, other type of metal may also be employed, provided that the metal prevents oxidation of the surfaces of the gate electrode 101 and the source electrode 104.

It is apparent that the present invention is not limited to the above embodiment, that may be modified and changed without departing from the scope and spirit of the invention.

What is claimed is:

1. A semiconductor device, comprising:
a semiconductor substrate including a device region;
interconnects, having a predetermined pattern and being provided on a surface of said semiconductor substrate;
an insulating film, provided to cover said interconnect;
a first electrode, provided on said semiconductor substrate to fill a space between said interconnects; and
a second electrode, electrically connected to said interconnect,
said first electrode being electrically connected to said device region, and said first electrode being composed of a solderable metal.

2. The semiconductor device according to claim 1,
wherein a source region and a drain region are provided in said device region,
said first electrode is a source electrode,
said second electrode is a gate electrode, and
a drain electrode is provided on a back surface of said semiconductor substrate.

3. The semiconductor device according to claim 1, wherein a diffusion barrier film is provided between an upper surface of said insulating film and said first electrode and between a portion of the upper surface of said semiconductor substrate and said first electrode.

4. The semiconductor device according to claim 1, wherein said first electrode is composed of a metal containing Cu.

5. The semiconductor device according to claim 1,
wherein a layer is formed to contact the upper surface of said first electrode, said layer being capable of inhibiting oxidation of a surface of said first electrode.

6. The semiconductor device according to claim 3,
wherein said diffusion barrier film is provided to follow a geometry of an upper surface of said insulating film, and
said first electrode is provided so that said diffusion barrier film is embedded within said first electrode.

7. The semiconductor device according to claim 2, wherein a thickness of said source electrode is equal to or greater than 1.5 μm.
